(19) United States
(12) Patent Application Publication
(10) Pub. No.: US 2013/0049995 A1
(43) Pub. Date: Feb. 28, 2013

(54) ILLUMINATED KEYBOARD

(71) Applicants: Chun-Che Wu, Taipei (TW); Chien-Ming Su, Taipei (TW); Chun-Nan Su, Taipei (TW)

(72) Inventors: Chun-Che Wu, Taipei (TW); Chien-Ming Su, Taipei (TW); Chun-Nan Su, Taipei (TW)

(73) Assignee: PRIMAX ELECTRONICS LTD., Taipei (TW)

(21) Appl. No.: 13/364,939

(22) Filed: Feb. 2, 2012

(30) Foreign Application Priority Data
Aug. 26, 2011 (TW) 100130682

(51) Int. Cl. H03M 11/00

(52) U.S. Cl. 341/22

(57) ABSTRACT

An illuminated keyboard includes a plurality of keys, a first light-emitting element, a second light-emitting element, and a light guide plate. The first light-emitting element is for emitting a first light beam. The second light-emitting element is used for emitting a second light beam. The light guide plate includes a first light-guiding region, a second light-guiding region, and an internal laser-engraving region. The first light-guiding region is used for guiding the first light beam. The second light-guiding region is for guiding the second light beam. The internal laser-engraving region is arranged between the first light-guiding region and the second light-guiding region for isolating the first light beam from the second light beam. Moreover, the internal laser-engraving region is formed within the light guide plate without damaging the surface of the light guide plate, so that the guide plate has strong structural strength.

### FIELD OF THE INVENTION

The present invention relates to a keyboard, and more particularly to an illuminated keyboard with a luminous function.

### BACKGROUND OF THE INVENTION

A keyboard is one of the widely-used computer peripheral devices. Via the keyboard, the user may input characters and commands into a computer. Nowadays, the keyboard manufacturers make efforts in designing novel keyboards with diversified functions and increased user-friendliness. For operating the keyboard in a dark or dim environment, one of the conventional approaches is to install an electroluminance plate within the keyboard to be used as a light source. When the electroluminance plate is powered by electricity, the electroluminance plate is enabled to emit a light beam, and thus the keyboard exhibits an illuminating efficacy. However, since the electroluminescence plate is only able to emit a monochromatic light beam, the conventional keyboard illuminated in a single light color. In another conventional approach of operating the keyboard in a dark or dim environment, a light emitting diode (LED) is installed on the bottom of each key to be used as a dot light source. However, the way of installing the light emitting diode on the bottom of each key may increase the fabricating cost and result in a heat-dissipating problem of the keyboard.

For solving the above drawbacks, an illuminated keyboard is disclosed in for example Taiwanese Patent Publication No. TW200945113. FIG. 1 is a schematic top view illustrating the outward appearance of a conventional illuminated keyboard. As shown in FIG. 1, the conventional illuminated keyboard 10 comprises a plurality of keys such as numeric keys, symbol keys, alphabetic keys, arrow keys, space key, and function keys. Moreover, the alphabetic keys “W”, “A”, “S”, “D”, the space key, the input key “Enter” and the up/down/left/right arrow keys are illuminated in a color different from other keys. As shown in FIG. 1, the conventional key 10 is the keyboard for a notebook computer.

FIG. 2 is a schematic cross-sectional view illustrating the conventional illuminated keyboard of FIG. 1 taken along the line A-A′. As shown in FIG. 2, the conventional illuminated keyboard 10 comprises a keypad module 100 and an illumination module 200. The illumination module 200 is disposed under the keypad module 100. The keypad module 100 comprises a plurality of keys 112, 114, a plurality of elastic elements 120, a plurality of scissors-type connecting element 130 and a membrane switch circuit member 140. When one or more keys 112 and 114 are depressed by a user, a corresponding key signal is generated. In response to the key signal, a command is provided to a computer (not shown) that is in communication with the conventional illuminated keyboard 10, thereby controlling the execution of a corresponding program.

The illumination module 200 comprises a light-shading member 210, a light guide plate 220, a reflector 230, a first light-emitting element 240, and a second light-emitting element 250. The light guide plate 220 comprises a first light-guiding region 222, a second light-guiding region 224 and a light-shading region 226. The light-shading region 226 is arranged between the first light-guiding region 222 and the second light-guiding region 224. For example, the light-shading region 226 is a gap that divides the light guide plate 220 into the first light-guiding region 222 and the second light-guiding region 224 and separates the first light-guiding region 222 from the second light-guiding region 224. For enhancing the light-shading efficacy, the light-shading region 226 further contains a light-shading material (or a reflective material) 227. The light-shading material (or a reflective material) 227 is formed on the interface between the light-shading region 226 and at least one of the first light-guiding region 222 and the second light-guiding region 224.

In the illumination module 200, the first light-emitting element 240 is used for emitting a first color light beam (e.g. white light) to the first light-guiding region 222. The second light-emitting element 250 is used for emitting a second color light beam (e.g. blue light) to the second light-guiding region 224. The first light-guiding region 222 and the second light-guiding region 224 are separated from each other by the light-shading region 226, so that the first color light beam and the second color light beam are not mixed with each other.

The light-shading member 210 has a predetermined pattern. The first color light beam from the first light-emitting element 240 and the second color light beam from the second light-guiding region 224 are transmissible through the predetermined pattern, so that the possibility of scattering the light beams will be reduced. Moreover, the light-shading member 210 is thin resin film with a light-shading pigment or a light-shading coating. For example, light-shading member 210 is a polyethylene terephthalate (PET) thin film or a polyvinylchloride (PVC) thin film. The light-shading member 210 has a plurality of openings 215 corresponding to the locations of the keys to be illuminated. Consequently, the light beams can be guided to the light guide plate 220 and directed to the corresponding keys (e.g. the keys 112 and 114). Moreover, for preventing the light beams from being scattered through the region between every two adjacent keys, the openings 215 of the light-shading member 210 are smaller than the corresponding keys (see FIG. 2).

The light guide plate 220 is disposed under the light-shading member 210 for guiding the first color light beam and the second color light beam, so that the light guide plate 220 is served as a light transfer medium. The first light-guiding region 222, the second light-guiding region 224 and the light-shading region 226 are integrally formed. The second light-guiding region 224 is surrounded by the light-shading region 226 (i.e. the gap), so that the first light-guiding region 222, the second light-guiding region 224 and the light-shading region 226 are respectively defined (see FIG. 3).

FIG. 3 is a schematic top view illustrating the light guide element of the conventional illuminated keyboard. Please refer to FIGS. 2 and 3 again. The first light-emitting element 240 are located adjacent to at least one side of the first light guide region 222. The first color light beam from the first light-emitting element 240 is guided by the first light-guiding region 222 and transmitted through the openings 215 of the light-shading member 210, so that at least a specified key (e.g. the key 112) of the keypad module 100 is illuminated by the first color light beam. On the other hand, at least one second light-emitting element 250 is disposed within each second light-guiding region 224. The second color light beam from second first light-emitting element 250 is guided by the second light-guiding region 224 and transmitted through the openings 215 overlying the second light-guiding region 224, so that at least a specified key (e.g. the key 114) of the keypad module 100 corresponding to second light-guiding region 224 is illuminated by the second color light beam. It is noted that the position, size, numbers and distribution of the second light-guiding region 224 may be varied according to the specific keys to be illuminated by the second color light beam. For example, the second light-guiding regions 224 are disposed under the alphabetic keys “W”, “A”, “S” and “D” and have convex profiles. Alternatively, the second light-guiding region 224 is disposed under the space key and has a rectangular profile. The reflector 230 is disposed under the light guide plate 220. The first color light beam or the second color light beam scattered by the light guide plate 220 can be reflected by the reflector 230 to be reused, so that the light utilization efficiency is enhanced and the scattered light is reduced.

The first light-emitting element 240 and the second light-emitting element 250 are light emitting diodes for emitting different color light beams, so that the predetermined locations of the keypad module 100 are shown in different colors. For example, the first light-emitting element 240 is a white light LED and the second light-emitting element 250 is a blue light LED. Consequently, the keypad module 100 will exhibit a white-color area (e.g. the location of key 112) and a blue-color area (e.g. the location of the key 114).

From the above discussions, the configurations and operating principles of the conventional illuminated keyboard for exhibits various light colors have been described. The keys of the illuminated keyboard may exhibit various colors for facilitating the user to recognize and operate the keys of the illuminated keyboard in a dark or dim environment. However, since the light guide plate 220 has a plurality of light-shading regions 226 and each of the light-shading regions 226 is a broken gap, the light guide plate 220 has weak structural strength. In other words, the light guide plate 220 is readily damaged.

Therefore, there is a need of providing an illuminated keyboard with stronger structural strength so as to obviate the drawbacks encountered from the prior art.

### SUMMARY OF THE INVENTION

The present invention provides an illuminated keyboard with stronger structural strength.

In accordance with an aspect of the present invention, there is provided an illuminated keyboard. The illuminated keyboard includes a plurality of keys, a first light-emitting element, a second light-emitting element, and a first light guide plate. The first light-emitting element is disposed under the plurality of keys for emitting a first light beam. The second light-emitting element is disposed under the plurality of keys and located at a first side of the first light-emitting element for emitting a second light beam. The first light guide plate is disposed under the plurality of keys and located at a second side of the first light-emitting element. The first light guide plate includes a first light-guiding region, a second light-guiding region, and an internal laser-engraving region. The first light-guiding region is located at the second side of the first light-emitting element for guiding the first light beam to a first key area of the keys. The second light-guiding region is located at a second side of the second light-emitting element for guiding the second light beam to a second key area of the keys. The internal laser-engraving region is arranged between the first light-guiding region and the second light-guiding region for isolating the first light beam from the second light beam.

In an embodiment, the first light-emitting element and the second light-emitting element are both light emitting diodes. The first light beam is exhibited in a first color, and the second light beam is exhibited in a second color.

In an embodiment, the illuminated keyboard includes a membrane switch circuit member, a main circuit board, an illumination circuit board, and a base plate. The membrane switch circuit member is arranged between the keys and the first light guide plate, and includes a plurality of key intersections corresponding to the keys. The main circuit board is connected with the membrane switch circuit member and located at a first side of the membrane switch circuit member for providing a first electric power to the membrane switch circuit member. The illumination circuit board is arranged at a second side of the membrane switch circuit member for providing a second electric power to the first light-emitting element and the second light-emitting element. The first light-emitting element and the second light-emitting element are disposed on the illumination circuit board. The base plate is disposed under the keys for supporting the keys.

In an embodiment, each of the keys includes a keycap, a scissors-type connecting element, and an elastic element. The scissors-type connecting element is arranged between the base plate and the keycap for connecting the base plate and the keycap, and allowing the keycap to be moved upwardly and downwardly with respect to the base plate. The elastic element is arranged between the membrane switch circuit module and the keycap. When the keycap is pressed, the elastic element is compressed to push against the membrane switch circuit module, so that a corresponding key intersection is triggered. Whereas, when a depressing force exerted on the keycap is eliminated, an elastic force provided by the elastic element is acted on the keycap, so that the keycap is returned to an original position.

In an embodiment, each of the keys includes a keycap, a key housing, and an elastic element. The key housing is arranged between the base plate and the keycap for fixing the keycap. The elastic element is penetrated through the key housing, and arranged between the membrane switch circuit module and the keycap. When the keycap is pressed, the elastic element is compressed to push against the membrane switch circuit module, so that a corresponding key intersection is triggered. Whereas, when a depressing force exerted on the keycap is eliminated, an elastic force provided by the elastic element is acted on the keycap, so that the keycap is returned to an original position.

In an embodiment, the illuminated keyboard further includes a third light-emitting element and a second light guide plate. The third light-emitting element is disposed below the first light-emitting element for emitting a third light beam. The second light guide plate is disposed below the first light guide plate and located at a first side of the third light-emitting element for guiding the third light beam to a sub-area of the second key area.

In an embodiment, the third light-emitting element is disposed on an illumination circuit board, the third light-emitting element is a light emitting diode, and the third light beam is exhibited in a third color, wherein when the third light beam is directed to the sub-area of the second key area, the sub-area of the second key area is switched from the second color to a fourth color, which is mixed by the second color and the third color.

In an embodiment, the illuminated keyboard further includes a second reflector. The second reflector is disposed under the second light guide plate for reflecting the third light beam, so that the third light beam is introduced into the second light guide plate again.

In an embodiment, the illuminated keyboard further includes a first reflector. The first reflector is arranged between the first light guide plate and the second light guide plate for reflecting the first light beam, so that the first light beam is introduced into the first light guide plate again. The first reflector further includes at least one opening under the sub-area of the second key area. The third light beam is transmitted through the at least one opening and directed to the sub-area of the second key area.

In an embodiment, the illuminated keyboard further includes a fourth light-emitting element. The fourth light-emitting element is arranged at a second side of the third light-emitting element for emitting a fourth light beam. The second light guide plate includes a third light-guiding region, a fourth light-guiding region, and an additional internal laser-engraving region. The third light-guiding region is located at the first side of the third light-emitting element for guiding the third light beam to another sub-area of the first key area. The fourth light-guiding region is located at a side of the fourth light-emitting element for guiding the second light beam to the sub-area of the second key area. The additional internal laser-engraving region is arranged between the third light-guiding region and the fourth light-guiding region for isolating the third light beam from the fourth light beam.

In an embodiment, the internal laser-engraving region is formed in the first light guide plate by an internal laser-engraving technique.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic top view illustrating the outward appearance of a conventional illuminated keyboard;

FIG. 2 is a schematic cross-sectional view illustrating the conventional illuminated keyboard of FIG. 1 taken along the line A-A′;

FIG. 3 is a schematic top view illustrating the light guide element of the conventional illuminated keyboard;

FIG. 4 is a schematic exposed view illustrating an illuminated keyboard according to a first embodiment of the present invention;

FIG. 5 is a schematic cross-sectional view illustrating the illuminated keyboard according to the first embodiment of the present invention;

FIG. 6 is a schematic perspective view illustrating the light guide plate and the light-emitting elements of the illuminated keyboard according to the first embodiment of the present invention;

FIG. 7 is a schematic exposed view illustrating an illuminated keyboard according to a second embodiment of the present invention; and

FIG. 8 is a schematic cross-sectional view illustrating the illuminated keyboard according to the second embodiment of the present invention.

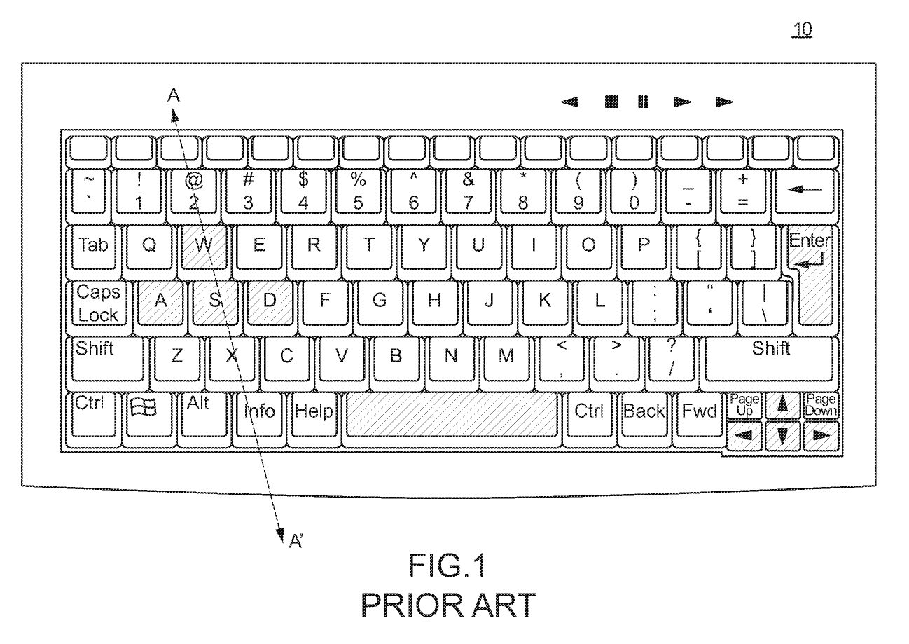

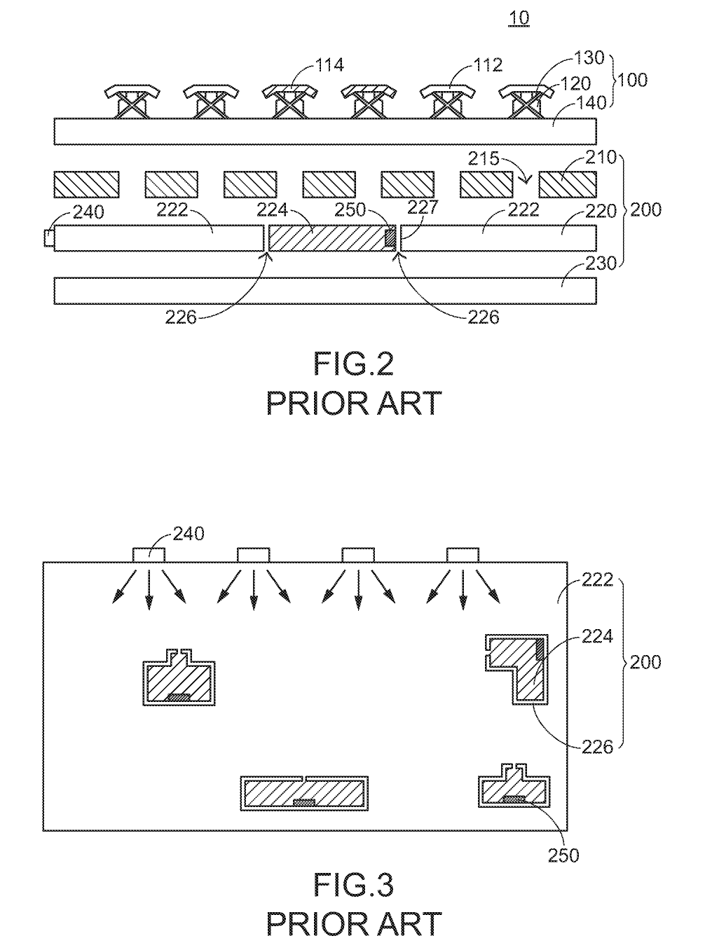

### DETAILED DESCRIPTION OF THE PREFERRED EMBODIMENT

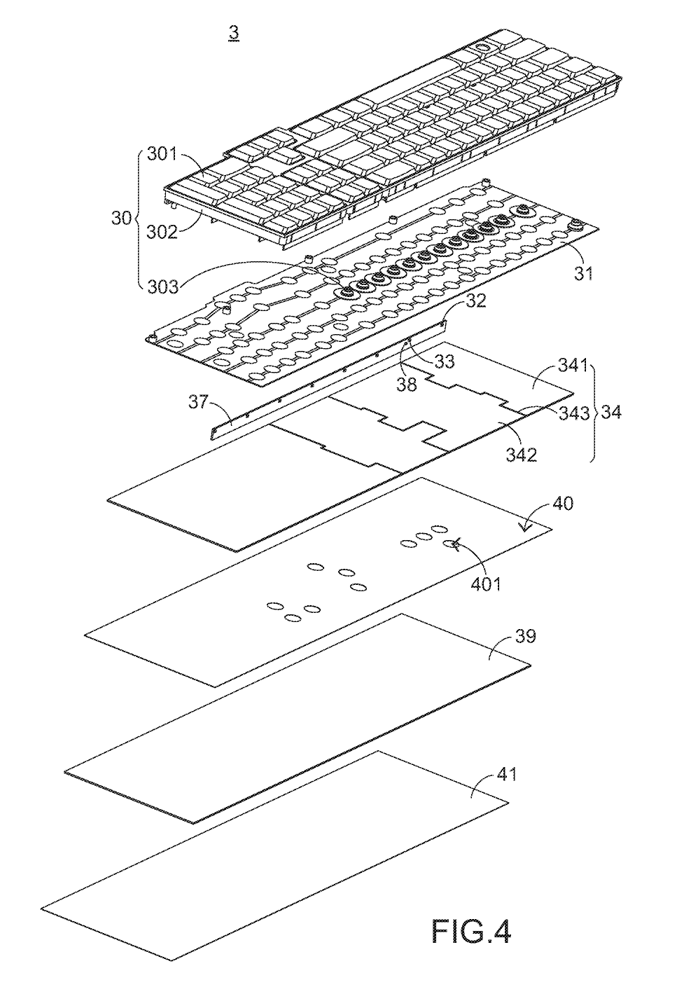

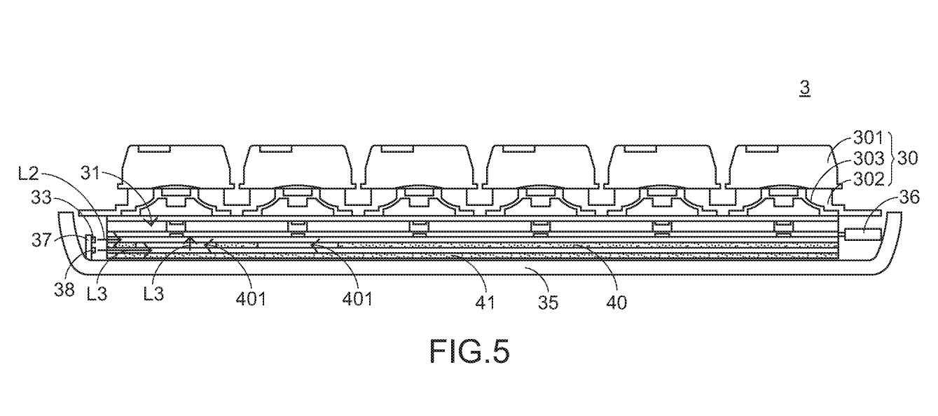

The present invention provides an illuminated keyboard. FIG. 4 is a schematic exposed view illustrating an illuminated keyboard according to a first embodiment of the present invention. FIG. 5 is a schematic cross-sectional view illustrating the illuminated keyboard according to the first embodiment of the present invention. As shown in FIGS. 4 and 5, the illuminated keyboard 3 comprises a plurality of keys 30, a membrane switch circuit member 31, a first light-emitting element 32, a second light-emitting element 33, a first light guide plate 34, a base plate 35, a main circuit board 36, a illumination circuit board 37, a third light-emitting element 38, a second light guide plate 39, a first reflector 40, and a second reflector 41. The key 30 comprises a keycap 301, a key housing 302 and an elastic element 303. From top to bottom, the keycap 301, the key housing 302, the elastic element 303, the membrane switch circuit member 31, the first light guide plate 34, the first reflector 40, the second light guide plate 39 and the second reflector 41 are sequentially shown. In this embodiment, the illuminated keyboard 3 is a keyboard for a desktop computer.

Please refer to FIGS. 4 and 5 again. The membrane switch circuit member 31 is arranged between the plurality of keys 30 and the first light guide plate 34. The membrane switch circuit member 31 has a plurality of key intersections corresponding to the keys 30. The main circuit board 36 is connected with the membrane switch circuit member 31 and arranged at a first side of the membrane switch circuit member 31 for providing a first electric power to the membrane switch circuit member 31. The illumination circuit board 37 is arranged at a second side of the of the membrane switch circuit member 31. The first light-emitting element 32, the second light-emitting element 33 and the third light-emitting element 38 are mounted on the illumination circuit board 37. The illumination circuit board 37 is used for providing a second electric power to the first light-emitting element 32, the second light-emitting element 33 and the third light-emitting element 38. The base plate 35 is disposed under the keys 30 for supporting the keys 30, the membrane switch circuit member 31, the first light guide plate 34, the first reflector 40, the second light guide plate 39 and the second reflector 41.

In each key 30, the key housing 302 is arranged between the base plate 35 and the keycap 301 for fixing the keycap 301. The elastic element 303 is penetrated through the key housing 302, and arranged between the membrane switch circuit member 31 and the keycap 301. When the keycap 301 is depressed, the elastic element 303 is compressed to push against the membrane switch circuit member 31, so that a corresponding key intersection of the membrane switch circuit module 31 is triggered to generate a key signal. Whereas, when the depressing force exerted on the key 301 is eliminated, an elastic force provided by the elastic element 303 is acted on the keycap 301. Due to the elastic force, the keycap 301 is returned to its original position.

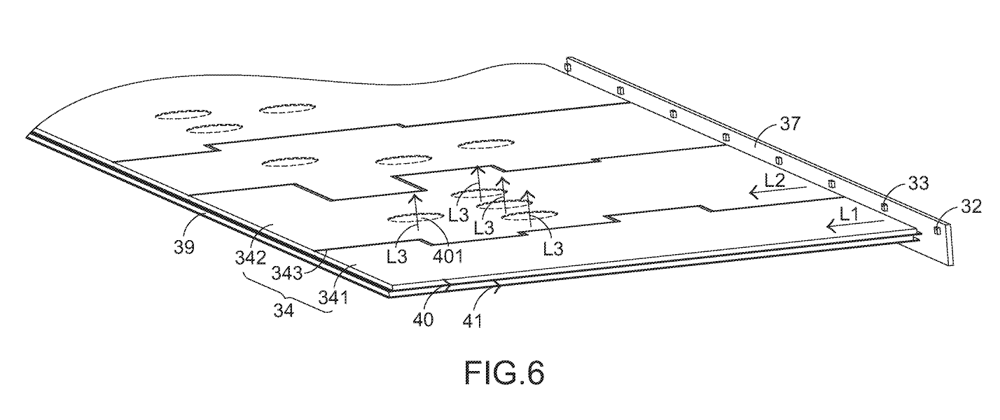

FIG. 6 is a schematic perspective view illustrating the light guide plate and the light-emitting elements of the illuminated keyboard according to the first embodiment of the present invention. The first light-emitting element 32 is mounted on the illumination circuit board 37 and disposed under the keys 30 for emitting a first light beam L1. The second light-emitting element 33 is mounted on the illumination circuit board 37, disposed under the keys 30 and located at a first side of the first light-emitting element 32 for emitting a second light beam L2. In this embodiment, the first light-emitting element 32 and the second light-emitting element 33 are both light emitting diodes. Moreover, the first light beam L1 is exhibited in a first color (e.g. a green color), and the second light beam L2 is exhibited in a second color (e.g. a blue color). The first light guide plate 34 is disposed under the keys 30 and located at a second side of the first light-emitting element 32. In this embodiment, the first light guide plate 34 comprises a first light-guiding region 341, a second light-guiding region 342, and an internal laser-engraving region 343. The first light-guiding region 341 is located at the second side of the first light-emitting element 32 for guiding the first light beam L1 to a first key area of the keys 30, e.g. the area containing the key “Tab”, the key “Cap Lock”, the key “Shift” and the key “Ctrl”. The second light-guiding region 342 is located at the second side of the first light-emitting element 32 for guiding the second light beam L2 to a second key area of the keys 30, e.g. the area containing a plurality of alphabetic keys. The internal laser-engraving region 343 is arranged between the first light-guiding region 341 and the second light-guiding region 342 for isolating the first light beam L1 from the second light beam L2, thereby preventing the first color and the second color from being mixed with each other. In this embodiment, the internal laser-engraving region 343 is formed in the first light guide plate 34 by performing an internal laser-engraving technique.

Please refer to FIGS. 5 and 6 again. The third light-emitting element 38 is disposed below the third light-emitting element 38 for emitting a third light beam L3. In this embodiment, the third light-emitting element 38 is also a light emitting diode. Moreover, the third light beam L3 is exhibited in a third color (e.g. a red color). The first reflector 40 is arranged between the first light guide plate 34 and the second light guide plate 39 for reflecting the first light beam L1, so that the first light beam L1 is directed to the first light guide plate 34 again. The first reflector 40 has a plurality of openings 401. The openings 401 are disposed under a sub-area of the second key area, e.g. the area containing the alphabetic keys “W”, “A”, “S” and “D”. Moreover, the third light beam L3 is transmissible through the openings 401 and directed to the sub-area of the second key area.

The second light guide plate 39 is disposed under the first light guide plate 34 and located at a side of the third light-emitting element 38 for guiding the third light beam L3 to be transmitted through the openings 401 and directed to the second key area. Like the first reflector 40, the second reflector 41 is disposed under the second light guide plate 39 for reflecting the third light beam L3, so that the third light beam L3 is directed to the second light guide plate 39 again.

Please refer to FIGS. 5 and 6 again. In the illuminated keyboard 3, the first light beam L1 from the first light-emitting element 32 is introduced into the first light guide plate 34. The first light beam L1 is guided by the first light-guiding region 341 to be directed to the first key area. Meanwhile, the first key area is exhibited in the first color (i.e. the green color). Similarly, the second light beam L2 from the second light-emitting element 33 is introduced into the first light guide plate 34. The second light beam L2 is guided by the second light-guiding region 342 to be directed to the second key area. Meanwhile, the second key area is exhibited in the second color (i.e. the blue color). When the first light beam L1 and the second light beam L2 are respectively guided by the first light-guiding region 341 and the second light-guiding region 342, the internal laser-engraving region 343 between the first light-guiding region 341 and the second light-guiding region 342 can isolate the first light beam L1 from the second light beam L2, thereby preventing the first color and the second color from being mixed with each other. In such way, the user can clearly recognize the locations of different keys when the illuminated keyboard 3 is operated in a dark or dim environment.

When the third light beam L3 is introduced into the second light guide plate 39, the third light beam L3 is guided by the second light guide plate 39 to be transmitted through the openings 401 and directed to the sub-area of the second key area. Consequently, the sub-area of the second key area is exhibited in a mixed color of the original color (i.e. the second color) and the third color of the third light beam L3. That is, the second key area is switched from the second color (i.e. the blue color) to a fourth color (e.g. a purple color). The fourth color is the mixed color of the second color and the third color. According to the distinguished color (i.e. the fourth color), the user can easily recognize the location of the sub-area of the second key area (i.e. the area containing the alphabetic keys “W”, “A”, “S” and “D”) from the plurality of alphabetic keys with the second color.

It is noted that the internal laser-engraving region 343 of the first light guide plate 34 is formed by an internal laser-engraving technique. The internal laser-engraving technique is performed to focusing a pulsed laser beam onto an internal position of the first light guide plate 34. Since the intensity of the pulsed laser beam on the surface of the first light guide plate 34 is lower than a breakdown threshold value, the surface of the first light guide plate 34 is not damaged. On the other hand, by controlling the intensity of the pulsed laser beam on the internal position of the first light guide plate 34 to be higher than the breakdown threshold value, the internal portion of the first light guide plate 34 is locally molten and vaporized. In such way, micrometer-sized micro-cracks from vaporization are generated within the first light guide plate 34. That is, the micro-cracks constitute the internal laser-engraving region 343, and the surface of the first light guide plate 34 is not damaged. When a light beam is directed to the internal laser-engraving region 343 (i.e. the micro-cracks), the light beam is scattered by the micro-cracks and fails to be transmitted through the internal laser-engraving region 343. Consequently, the internal laser-engraving region 343 is able to isolate the first light beam L1 from the second light beam L2. From the above discussions, since the internal laser-engraving region 343 is formed within the first light guide plate 34 and the surface of the first light guide plate 34 is not damaged, the first light guide plate 34 has good light-isolating efficacy and strong structural strength. In other words, the possibility of damaging the first light guide plate 34 is minimized.

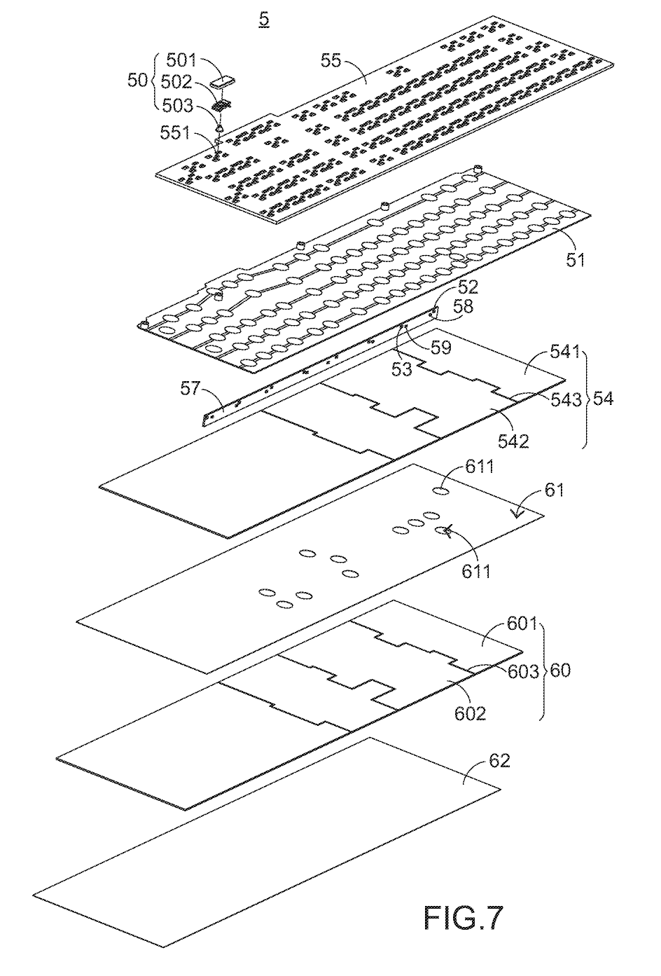

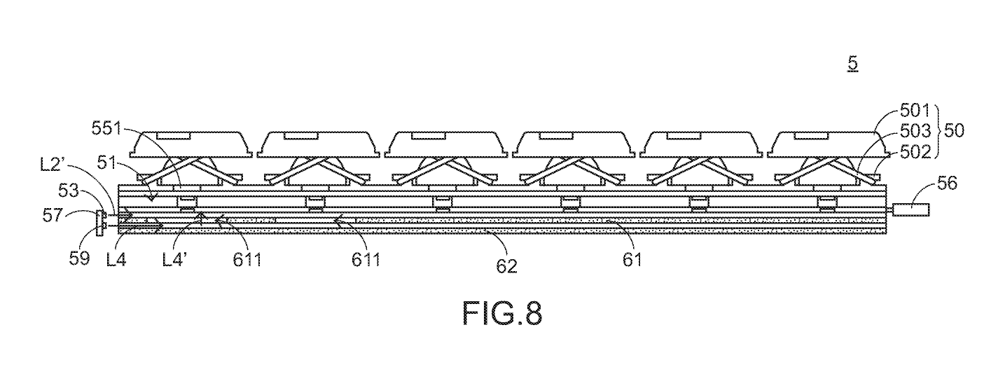

The present invention further provides a second embodiment. FIG. 7 is a schematic exposed view illustrating an illuminated keyboard according to a second embodiment of the present invention. FIG. 8 is a schematic cross-sectional view illustrating the illuminated keyboard according to the second embodiment of the present invention. As shown in FIGS. 7 and 8, the illuminated keyboard 5 comprises a plurality of keys 50, a membrane switch circuit member 51, a first light-emitting element 52, a second light-emitting element 53, a first light guide plate 54, a base plate 55, a main circuit board 56, a illumination circuit board 57, a third light-emitting element 58, a fourth light-emitting element 59, a second light guide plate 60, a first reflector 61, and a second reflector 62. Except for the following four items, the configurations and functions of the illuminated keyboard 5 of the second embodiment are similar to those of the first embodiment, and are not redundantly described herein.

Firstly, the key 50 of the illuminated keyboard 5 of this embodiment comprises a keycap 501, a scissors-type connecting element 502 and an elastic element 503. The scissors-type connecting element 502 is arranged between the base plate 55 and the keycap 501 for connecting the base plate 55 and the keycap 501, so that the keycap 501 is movably upwardly and downwardly relative to the base plate. That is, the illuminated keyboard 5 of this embodiment is a keyboard for a notebook computer. Moreover, the base plate 55 has a plurality of perforations 551. The elastic element 503 may be penetrated through a corresponding perforation 551 to trigger the membrane switch circuit member 51. Secondly, the illuminated keyboard 5 of this embodiment additionally includes the fourth light-emitting element 59. The fourth light-emitting element 59 is located at another side of the third light-emitting element 58 for emitting a fourth light beam L4′ with a fifth color.

Thirdly, the first reflector 61 of the illuminated keyboard 5 of this embodiment has at least one additional opening 611 corresponding to a sub-area of the first key area (e.g. the area containing the key “Shift”). Fourthly, the second light guide plate 60 of the illuminated keyboard 5 of this embodiment comprises a third light-guiding region 601, a fourth light-guiding region 602, and another internal laser-engraving region 603. The third light-guiding region 601 is located at a side of the third light-emitting element 58 for guiding the third light beam to be transmitted through the opening 611 underlying the key “Shift” and directed to the sub-area of the first key area (e.g. the area containing the key “Shift”). The fourth light-guiding region 602 is located at a side of the fourth light-emitting element 59 for guiding the fourth light beam to be transmitted through the opening 611 and directed to the sub-area of the second key area (i.e. the area containing the alphabetic keys “W”, “A”, “S” and “D”). The internal laser-engraving region 603 is arranged between the third light-guiding region 601 and the fourth light-guiding region 602 for isolating the third light beam from the fourth light beam, thereby preventing the third color and the fourth color from being mixed with each other. In this embodiment, the internal laser-engraving region 603 is also formed in the second light guide plate 60 by an internal laser-engraving technique.

Please refer to FIGS. 7 and 8 again. In the illuminated keyboard 5, the first light beam (not shown) emitted by the first light-emitting element 52 is introduced into the first light guide plate 54. The first light beam is guided by the first light-guiding region 541 of the first light guide plate 54 to be directed to the first key area of the keys 50. Meanwhile, the first key area is exhibited in the first color (i.e. the green color). Similarly, the second light beam L2′ emitted by the second light-emitting element 53 is introduced into the first light guide plate 54. The second light beam L2′ is guided by the second light-guiding region 542 of the first light guide plate 54 to be directed to the second key area of the keys. Meanwhile, the second key area is exhibited in the second color of the second light beam L2′. When the first light beam and the second light beam L2′ are respectively guided by the first light-guiding region 541 and the second light-guiding region 542, the internal laser-engraving region 543 between the first light-guiding region 541 and the second light-guiding region 542 can isolate the first light beam from the second light beam L2′, thereby preventing the first color and the second color from being mixed with each other.

When a third light beam (not shown) is emitted by the third light-emitting element 58, the third light beam is introduced into the second light guide plate 60. The third light beam is guided by the third light-guiding region 601 of the second light guide plate 60 to be transmitted through the openings 611 of the first reflector 61 and directed to the sub-area of the first key area (e.g. the area containing the key “Shift”). Consequently, the sub-area of the first key area is exhibited in a mixed color of the original color (i.e. the first color) and the third color of the third light beam. That is, the sub-area of the first key area is switched from the first color to a fourth color. The fourth color is a mixed color of the first color and the third color. Similarly, when a fourth light beam L4′ with a fifth color is emitted by the fourth light-emitting element 59, the fourth light beam L4′ is introduced into the second light guide plate 60. The fourth light beam L4′ is guided by the fourth light-guiding region 602 of the second light guide plate 60 to be transmitted through the openings 611 of the first reflector 61 and directed to the sub-area of the second key area (i.e. the area containing the alphabetic keys “W”, “A”, “S” and “D”). Consequently, the sub-area of the second key area is exhibited in a mixed color of the original color (i.e. the second color) and the fifth color of the fourth light beam L4′. That is, the sub-area of the second key area is switched from the second color to a sixth color. The sixth color is a mixed color of the second color and the fifth color. Of course, the internal laser-engraving region 603 of the second light guide plate 60 can isolate the third light beam from the fourth light beam L4′, thereby preventing the third color and the fourth light beam L4′ from being mixed with each other.

From the above two embodiments, the illuminated keyboard of the present invention can exhibit various light colors. According to the various light colors, the user can clearly recognize the locations of different key areas with the naked eyes. Moreover, the light color exhibited by the sub-area may be distinguished from the light color of the key area, so that the user can recognize the location of the specified sub-area. Moreover, for preventing various light color beams from being mixed with each other, the light guide plate of the illuminated keyboard of the present invention has an internal laser-engraving region for blocking the light beams. Since the internal laser-engraving region is formed within the first light guide plate by an internal laser-engraving technique, the surface of the light guide plate is not damaged. That is, the light guide plate has strong structural strength, and thus the possibility of damaging the illuminated keyboard will be minimized.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An illuminated keyboard, comprising:
a plurality of keys;
a first light-emitting element disposed under said plurality of keys for emitting a first light beam;
a second light-emitting element disposed under said plurality of keys and located at a first side of said first light-emitting element for emitting a second light beam; and
a first light guide plate disposed under said plurality of keys and located at a second side of said first light-emitting element, wherein said first light guide plate comprises:
a first light-guiding region located at said second side of said first light-emitting element for guiding said first light beam to a first key area of said keys;
a second light-guiding region located at a second side of said second light-emitting element for guiding said second light beam to a second key area of said keys; and
an internal laser-engraving region arranged between said first light-guiding region and said second light-guiding region for isolating said first light beam from said second light beam.

2. The illuminated keyboard according to claim 1 wherein said first light-emitting element and said second light-emitting element are both light emitting diodes, wherein said first light beam is exhibited in a first color, and said second light beam is exhibited in a second color.

3. The illuminated keyboard according to claim 1 further comprising:
a membrane switch circuit member arranged between said keys and said first light guide plate, and comprising a plurality of key intersections corresponding to said keys;
a main circuit board connected with said membrane switch circuit member and located at a first side of said membrane switch circuit member for providing a first electric power to said membrane switch circuit member;
an illumination circuit board arranged at a second side of said membrane switch circuit member for providing a second electric power to said first light-emitting element and said second light-emitting element, wherein said first light-emitting element and said second light-emitting element are disposed on said illumination circuit board; and
a base plate disposed under said keys for supporting said keys.

4. The illuminated keyboard according to claim 3 wherein each of said keys comprises:
a keycap;
a scissors-type connecting element arranged between said base plate and said keycap for connecting said base plate and said keycap, and allowing said keycap to be moved upwardly and downwardly with respect to said base plate; and
an elastic element arranged between said membrane switch circuit module and said keycap, wherein when said keycap is pressed, said elastic element is compressed to push against said membrane switch circuit module, so that a corresponding key intersection is triggered, wherein when a depressing force exerted on said keycap is eliminated, an elastic force provided by said elastic element is acted on said keycap, so that said keycap is returned to an original position.

5. The illuminated keyboard according to claim 3 wherein each of said keys comprises:
a keycap;
a key housing arranged between said base plate and said keycap for fixing said keycap; and
an elastic element penetrated through said key housing, and arranged between said membrane switch circuit module and said keycap, wherein when said keycap is pressed, said elastic element is compressed to push against said membrane switch circuit module, so that a corresponding key intersection is triggered, wherein when a depressing force exerted on said keycap is eliminated, an elastic force provided by said elastic element is acted on said keycap, so that said keycap is returned to an original position.

6. The illuminated keyboard according to claim 1 further comprising:
a third light-emitting element disposed below said first light-emitting element for emitting a third light beam; and
a second light guide plate disposed below said first light guide plate and located at a first side of said third light-emitting element for guiding said third light beam to a sub-area of said second key area.

7. The illuminated keyboard according to claim 6 wherein said third light-emitting element is disposed on an illumination circuit board, said third light-emitting element is a light emitting diode, and said third light beam is exhibited in a third color, wherein when said third light beam is directed to said sub-area of said second key area, said sub-area of said second key area is switched from said second color to a fourth color, which is mixed by said second color and said third color.

8. The illuminated keyboard according to claim 7 further comprising a second reflector, which is disposed under said second light guide plate for reflecting said third light beam, so that said third light beam is introduced into said second light guide plate again.

9. The illuminated keyboard according to claim 6 further comprising a first reflector, which is arranged between said first light guide plate and said second light guide plate for reflecting said first light beam, so that said first light beam is introduced into said first light guide plate again, wherein said first reflector further comprises at least one opening under said sub-area of said second key area, and said third light beam is transmitted through said at least one opening and directed to said sub-area of said second key area.

10. The illuminated keyboard according to claim 6 further comprising a fourth light-emitting element, which is arranged at a second side of said third light-emitting element for emitting a fourth light beam, wherein said second light guide plate comprises:
a third light-guiding region located at said first side of said third light-emitting element for guiding said third light beam to another sub-area of said first key area; and
a fourth light-guiding region located at a side of said fourth light-emitting element for guiding said second light beam to said sub-area of said second key area; and
an additional internal laser-engraving region arranged between said third light-guiding region and said fourth light-guiding region for isolating said third light beam from said fourth light beam.

11. The illuminated keyboard according to claim 1 wherein said internal laser-engraving region is formed in said first light guide plate by an internal laser-engraving technique.
